(19) United States
(12) Patent Application Publication
(10) Pub. No.: US 2007/0045738 A1
(43) Pub. Date: Mar. 1, 2007

(54) METHOD FOR THE MANUFACTURE OF A STRAINED SILICON-ON-INSULATOR STRUCTURE

(75) Inventors: Andrew M. Jones, St. Peters, MO (US); Lu Fei, St. Peters, MO (US)

Correspondence Address: SENNIGER POWERS, ONE METROPOLITAN SQUARE, 16TH FLOOR, ST LOUIS, MO, 63102, US

(73) Assignee: MEMC ELECTRONIC MATERIALS, INC., St. Peters, MO (US)

(21) Appl. No.: 11/461,956

(22) Filed: Aug. 2, 2006

Related U.S. Application Data
(60) Provisional application No. 60/712,022, filed on Aug. 26, 2005.

(51) Int. Cl. H01L 27/12; H01L 21/30

(52) U.S. Cl. 257/347; 438/455; 438/149; 438/479; 438/517; 257/66

(57) ABSTRACT

The present invention is directed to a strained silicon on insulator (SSOI) structure having improved surface characteristics, such as reduced roughness, low concentration of LPDs, and lower contamination, and a method for making such a structure.

### REFERENCE TO RELATED APPLICATIONS

This application claims priority from U.S. provisional application Ser. No. 60/712,022 filed on Aug. 26, 2005, the entire disclosure of which is incorporated herein by reference.

### FIELD OF THE INVENTION

The present invention relates generally to a strained silicon-on-insulator (SSOI) structure. More particularly, the present invention is directed to an SSOI structure wherein the strained silicon layer has improved surface properties. The present invention is further directed to a method for making such a structure.

### BACKGROUND OF THE INVENTION

Silicon-on-insulator (SOI) structures generally comprise a handle wafer, a semiconductor device layer, and a dielectric insulating layer between the handle wafer and the device layer. By insulating the device layer from the handle wafer of the SOI structure, the device layer yields reduced leakage currents and lower capacitance. Strained silicon-on-insulator (SSOI) structures for semiconductor devices combine the benefits of SOI technology with strained silicon technology, with the strained silicon layer providing enhanced carrier mobility.

The strained silicon-on-insulator structure may be fabricated or manufactured in a number of ways. For example, in one approach, a relaxed silicon-germanium (SiGe) layer is formed on an insulator by one of several techniques known in the art, such as: (i) separation by implantation of oxygen (known as “SIMOX”, see, e.g., U.S. Pat. No. 5,436,175); (ii) wafer bonding followed by back etching; (iii) wafer bonding followed by hydrogen exfoliation layer transfer; or (iv) recrystallization of amorphous material. This is followed by the epitaxial deposition or growth of a strained silicon layer on the SiGe layer. The relaxed SiGe-on-insulator layer serves as the template for inducing strain in the Si layer, the induced strain typically being greater than approximately 10⁻³.

Such a structure has limitations, however. For example, it is not conducive to the production of fully-depleted strained-semiconductor-on-insulator devices in which the layer over the insulating material must be thin enough (e.g., less than about 300 angstroms) to allow for full depletion of the layer during device operation. Additionally, the relaxed SiGe layer adds to the total thickness of the layer over the insulating material, and thus makes it difficult to achieve the thicknesses required for fully depleted silicon-on-insulator device fabrication.

Such problems may be alleviated if the strained SOI structure has the strained Si layer directly on the insulating material. (See, e.g., published U.S. Patent Application No. 2004/0005740, the entire content of which is incorporated herein for all purposes). This may be achieved, for example, by utilizing both wafer bonding and separation by implantation techniques. Specifically, a relaxed layer of, for example, SiGe may be formed on the surface of one wafer or substrate. A strained silicon layer may then be formed by, for example, epitaxial deposition on the surface of the relaxed layer. Hydrogen ions may then be implanted into the relaxed layer to define a cleave or separation plane therein according to any technique generally known in the art, such as, e.g., the process disclosed in U.S. Pat. No. 6,790,747. The resulting wafer may then be bonded to a second wafer or substrate, having a dielectric insulating layer on the surface thereof, the surface of the strained layer being bound to the dielectric layer surface. Once bound, the resulting structure may then be separated along the cleave or separation plane to yield an SSOI structure.

Preparing an SSOI structure in this way is not without problems, however. For example, the resulting structure still has a portion of the relax SiGe layer present on the surface of the strained silicon layer that must subsequently be removed. Approaches to remove the relaxed layer that have been typically employed to-date involve the use of etchants that yield undesirable surface characteristics. For example, the resulting surface of the strained silicon layer is often unacceptably rough, and/or includes an unacceptable number of light point defects (LPDs), and/or has an unacceptable contaminant concentration. Additionally, etchants typically employed to-date act to increase the overall cost of processing, due to their cost and/or due to the safety and environmental precautions that must be taken because of their hazardous components. Finally, etching might not be used alone; rather, it may be employed to remove the relaxed SiGe layer as part of a multi-step approach further comprising, for example, grinding, lapping, polishing, and/or wet oxidation.

### SUMMARY OF THE INVENTION

Briefly, therefore, the present invention is directed to a method for the preparation of a strained silicon on insulator structure comprising forming a relaxed silicon-comprising layer on a surface of a donor wafer; forming a strained silicon layer on a surface of the relaxed silicon-comprising layer; forming a dielectric layer on a surface of a handle wafer; bonding the donor wafer and the handle wafer to form a bonded structure, wherein a bond interface is formed between the strained silicon layer and the dielectric layer; separating the bonded structure along a separation plane within the relaxed silicon-comprising layer, such that the strained silicon layer on said handle wafer has a residual relaxed silicon-comprising layer on the surface thereof having a thickness of at least about 20 nm; and, etching the separated handle wafer to substantially remove the residual silicon-comprising layer to expose a surface of the strained silicon layer.

In another aspect, the present invention is directed to a method for the preparation of a strained silicon on insulator structure comprising forming a relaxed silicon-comprising layer on a surface of a donor wafer; forming a strained silicon layer on a surface of the relaxed silicon-comprising layer; forming a dielectric layer on a surface of a handle wafer; bonding the donor wafer and the handle wafer, wherein a bond interface is formed between the strained silicon layer and the dielectric layer; separating the bonded structure along a separation plane within the relaxed silicon-comprising layer, such that the strained silicon layer on said handle wafer has a residual relaxed silicon-comprising layer on the surface thereof; and etching the separated handle wafer to substantially remove the residual silicon-comprising layer to expose a surface of the strained silicon layer, wherein the etching comprises exposing the separated handle wafer to a megasonic agitation.

In yet another aspect, the present invention is directed to a method for the preparation of a strained silicon on insulator structure comprising forming a relaxed silicon-comprising layer comprising SiGe having at least about 10% Ge on a surface of a donor wafer; forming a strained silicon layer on a surface of the relaxed silicon-comprising layer; forming a dielectric layer on a surface of a handle wafer; bonding the donor wafer and the handle wafer, wherein a bond interface is formed between the strained silicon layer and the dielectric layer; separating the bonded structure along a separation plane within the relaxed silicon-comprising layer, such that the strained silicon layer on said handle wafer has a residual relaxed silicon-comprising layer on the surface thereof; and, etching the separated handle wafer to substantially remove the residual silicon-comprising layer to expose a surface of the strained silicon layer, wherein the etching comprises exposing the handle wafer to an etchant with a selectivity ratio for SiGe:Si of at least about 3:1.

The present invention is further directed to a method for the preparation of a strained silicon on insulator structure comprising forming a relaxed silicon-comprising layer on a surface of a donor wafer; forming a strained silicon layer on a surface of the relaxed silicon-comprising layer; forming a dielectric layer on a surface of a handle wafer; bonding the donor wafer and the handle wafer, wherein a bond interface is formed between the strained silicon layer and the dielectric layer; separating the bonded structure along a separation plane within the relaxed silicon-comprising layer, such that the strained silicon layer on said handle wafer has a residual relaxed silicon-comprising layer on the surface thereof having a thickness of at least about 20 nm; and, etching the separated handle wafer to substantially remove the residual silicon-comprising layer to expose a surface of the strained silicon layer, wherein the exposed strained silicon layer surface has less than about 0.35 LPDs/cm².

The present invention is also directed to a silicon on insulator structure comprising a strained silicon layer, a handle wafer, and a dielectric layer therebetween, wherein a surface of the strained silicon layer has less than about 0.35 LPDs/cm².

In yet another aspect, the present invention is also directed to a silicon on insulator structure comprising a strained silicon layer, a handle wafer, and a dielectric layer therebetween, wherein the surface of the strained silicon layer has less than about 1×10¹⁰ Ge atoms/cm² and an RMS roughness of less than about 1 nm.

Other objects and features of this invention will be in part apparent and in part pointed out hereinafter.

### BRIEF DESCRIPTION OF THE DRAWINGS

FIG. 1A is a cross-sectional, schematic drawing of a donor wafer (12) having on a surface thereof a relaxed silicon-comprising layer (13) and a strained silicon layer (14). The dashed line (17) in the relaxed silicon-comprising layer (13) represents a separation or cleave plane, present therein.

FIG. 1B is a cross-sectional, schematic drawing of a handle wafer (16) having a dielectric layer (15) disposed on a surface thereof, prior to bonding with the wafer of 1A.

FIG. 2 is a cross-sectional, schematic drawing of a bonded structure (20) resulting from contacting the surface of the strained silicon layer (14) on the donor wafer (illustrated in FIG. 1A) to the surface of the dielectric layer (15) of the handle wafer (illustrated in FIG. 1B).

FIG. 3 is a cross-sectional, schematic drawing which illustrates separation of the bonded structure (20) along the separation or cleave plane (17) in the relaxed silicon-comprising layer (13), and thus the transfer of the strained silicon layer (14), with a residual portion of the relaxed silicon-comprising layer (33) thereon, onto the dielectric layer (15) of handle wafer (16).

FIG. 4 is a cross-sectional, schematic drawing of the strained silicon-on-insulator structure of the present invention (40), the residual portion of the relaxed silicon-comprising layer having been substantially removed from the surface of the transferred strained silicon layer (14).

With respect to the Figures, corresponding reference characters indicate corresponding parts throughout the several views of the drawings.

### DETAILED DESCRIPTION OF THE PREFERRED EMBODIMENTS

In accordance with the present invention, it has been discovered that a strained silicon-on-insulator structure, wherein the strained silicon layer is in direct contact with a dielectric layer present on a handle or support wafer, may be prepared such that the surface of the strained silicon layer has improved surface characteristics while being substantially free of any relaxed layer thereon. As further detailed herein below, it has been discovered that once a strained silicon layer has been formed on (e.g., deposited on or transferred onto) a dielectric layer, an etchant comprising NH₄OH, H₂O₂, and H₂O may be used to efficiently and selectively remove a residual portion of a relaxed layer present on the strained silicon layer.

It is to be noted that essentially any of the techniques known generally for preparing an SSOI structure, which result in the presence of a relaxed layer on the surface of the strained silicon layer, may be employed in accordance with the present invention (see, e.g., U.S. Pat. No. 6,790,747; U.S. Patent App. Pub. Nos. 2004/0005740 and 2004/0031979). These techniques include, for example, bond and layer transfer (or bond and separate) techniques, and bond and grind or etch back techniques. Preferably, however, the process of the present invention utilizes wafer bonding and layer transfer techniques. Accordingly, the present invention will be set forth in greater detail below in the context of these wafer bonding and layer transfer techniques. It is to be understood, however, that this is for purposes of illustration and, therefore, should not be viewed in a limiting sense. It is to be further understood that in the practice of the present invention, these techniques may be suitably carried out using a variety of apparatus and process conditions well-known in the art and, in some instances, may be omitted or combined with other techniques and conditions without departing from the scope of the present invention.

Formation of the Strained Silicon Layer

Generally speaking, the wafer bonding and layer transfer techniques employed to prepare the strained silicon on insulator structure of the present invention involves the preparation of two separate structures, bonding them together along a bond interface, and then delaminating them along a separation plane that is different from the bond interface and which has been formed via an implantation technique. Each structure comprises a substrate or supporting wafer, which can comprise any material having a lattice constant different from that of pure silicon or capable of having a layer of such material formed thereon, onto which pure silicon can subsequently be formed. For example, the substrate or supporting wafer may be made of quartz or sapphire, but it more commonly comprises a semiconductor material, such as silicon (e.g., single crystal silicon, prepared for example in accordance with the Czochralski method), germanium, or silicon-germanium (SiGe). In one preferred embodiment, the substrates comprise a single crystal silicon wafer, the wafer having a diameter of at least about 75 mm, 100 mm, 150 mm, 200 mm, 300 mm, or more.

One substrate will be referred to hereinafter as the “handle wafer.” The handle wafer has a dielectric layer directly deposited on a surface thereof, and serves as the substrate for the final SSOI structure. The other substrate will be referred to hereinafter as the “donor wafer.” The donor wafer has a fully or partially relaxed (generally referred to hereinafter as “relaxed”) layer directly deposited on a surface thereof and, in one embodiment, serves as the substrate upon which the strained silicon layer is formed prior to a wafer bonding step. It is to be noted that the donor wafer's relaxed layer can comprise any material upon which a strained silicon layer may be formed, such as Ge, SiGe, or other III-V compounds. In one preferred embodiment, the relaxed layer is a silicon-comprising layer. While the discussion hereinafter refers specifically to this preferred embodiment, it is to be understood that the scope of potential materials is not restricted to silicon-comprising materials.

Donor Wafer Structure

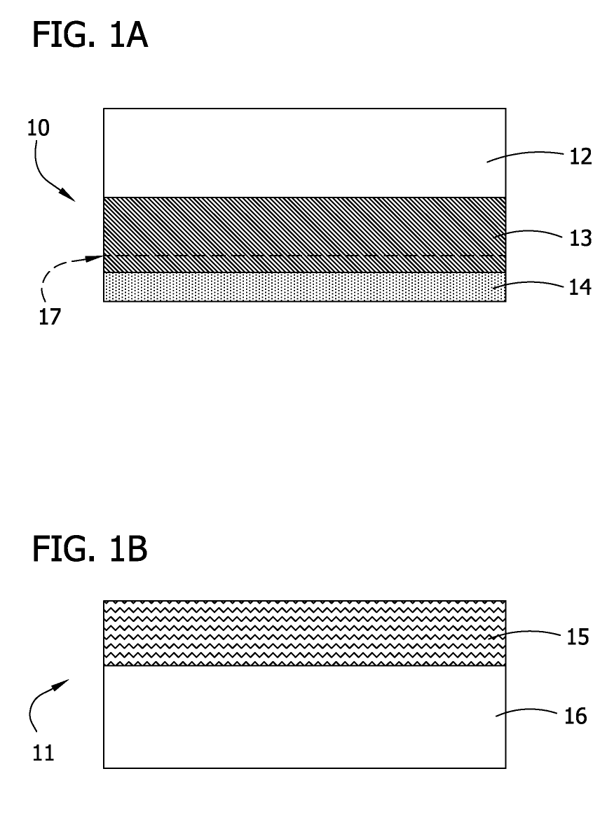

Referring now to FIG. 1A, the donor wafer structure comprises a donor wafer or substrate 12, a relaxed silicon-comprising layer 13 on a surface thereof, this layer having a lattice constant different than that of a relaxed silicon crystal lattice, and a strained silicon layer 14 on a surface of the relaxed silicon-comprising layer. Typically, the relaxed silicon-comprising layer has a lattice constant that differs from the relaxed silicon crystal lattice constant by at least about 0.25%. In one preferred embodiment, the silicon-comprising layer is SiGe. The specific composition of the relaxed SiGe layer may vary according to the desired level of lattice strain to be induced in the strained silicon layer. Typically, the SiGe layer comprises at least about 10% Ge, and in some instances may comprise about 15%, about 20%, about 25%, about 35%, about 50% or more (e.g., 60%, 70%, 80%, 90% or more). In one preferred embodiment, however, the SiGe layer has a Ge concentration in the range of at least about 10% to less than about 50%, or from at least about 15% to less than about 45%, with a concentration of at least about 20% to less than about 40% Ge being preferred. It is to be noted that the actual percentage of Ge, or the precise composition of the relaxed layer, may be different from these SiGe compositions without departing from the scope of the invention depending on the desired application.

Essentially any technique generally known in the art may be used to form the relaxed silicon-comprising (e.g., SiGe) layer; see, e.g., U.S. Pat. Nos. 5,221,413; 5,442,205, and 6,573,126. For example, one of the known epitaxial deposition techniques may be used to form such a relaxed layer. Generally speaking, the relaxed layer is as thin as possible, so long as the crystal lattice still exhibits at least partially plastic relaxation. Typically, however, the relaxed layer has a substantially uniform thickness of at least about 0.1 microns. For example, the thickness typically ranges from about 0.1 microns to about 10 microns, or about 0.5 microns to about 5 microns.

A strained layer 14 of, for example, silicon is formed or deposited on the relaxed (e.g., SiGe) layer 13, the strain resulting from the difference in lattice constants between, for example, the strained silicon layer and the relaxed SiGe layer. A tensile strain results in a silicon strained layer when SiGe is employed as the relaxed layer to induce strain. Other relaxed layer compositions may alternatively induce a compressive strain in the strained layer.

Like the relaxed layer, essentially any technique generally known in the art may be used to form or deposit the strained layer on the relaxed layer such that strain is present in the layer after deposition thereof. In one preferred embodiment, one of the known epitaxial deposition techniques (e.g., atmospheric-pressure chemical vapor phase deposition (APCVD); low- or reduced-pressure CVD (LPCVD); ultra-high-vacuum CVD (UHVCVD); molecular beam epitaxy (MBE); or, atomic layer deposition (ALD)) is used, optionally in conjunction with precursors such as silane, disilane, trisilane, monoclorolsilane, diclorolsilane, and triclorolsilane. The epitaxial growth system may be a single-wafer or a multiple-wafer batch reactor. The growth system may also utilize a low-energy plasma to enhance layer growth kinetics. The strained layer may be formed at a relatively low temperature (e.g., less than 700° C.) in order to aid in the definition of an interface between the strained layer and the relaxed layer. Such a defined interface may enhance the subsequent separation or removal of the strained layer from the relaxed layer. In an embodiment in which the strained layer contains substantially 100% silicon, this layer may be formed in a deposition apparatus' dedicated chamber that is not exposed to, for example, a Ge source gas, thereby helping to avoiding cross-contamination and improving the quality of the interface between strained layer and relaxed layer. Additionally, the strained layer may be formed from an isotopically pure silicon precursor(s), which has better thermal conductivity than conventional Si. Higher thermal conductivity may help dissipate heat from devices subsequently formed on the strained layer, thereby maintaining the enhanced carrier mobilities provided by the strained layer.

Generally speaking, the strained layer 14 is grown to a substantially uniform thickness that is sufficient for subsequent device fabrication, but not thick enough for the crystal lattice at the exposed silicon surface to undergo significant plastic relaxation. Typically, therefore, the strained layer is grown to a thickness of between about 1 nm and about 100 nm, preferably between about 2 nm and about 80 nm, and more preferably between about 10 nm and about 60 nm. In one preferred embodiment, the thickness of the silicon layer is about 20 nm.

Referring again to FIG. 1A, either before or after the strained layer 14 is formed, ions, such as hydrogen ions (i.e., either H⁺ or H₂⁺), are implanted to a substantially uniform depth below the surface of relaxed layer 13 in order to define a separation or cleave plane 17 in the relaxed layer. As further detailed herein below, ions are typically implanted to a depth of at least about 10, 15, 20 nanometers (nm) or more below the surface of the relaxed layer (or interface between the relaxed layer and the strained layer, when the strained layer is present). Ion implantation may be achieved using means known in the art. For example, this implantation may be achieved in a manner similar to the process disclosed in U.S. Pat. No. 6,790,747. Implantation parameters may include, for example, implantation of hydrogen ions (H₂⁺) to a dose of about 2 to about 5×10¹⁶ ions/cm² at an energy of, for example, about 20 to about 100 keV (e.g., H₂⁺ may be implanted at an energy of 20 keV and a dose of 2.4×10¹⁶ ions/cm² through the strained layer and into the relaxed layer).

In this regard, it is to be noted that in an alternative embodiment, other implanted species may be used, such as H⁺ or He⁺, with the dose and energy being adjusted accordingly.

It is to be further noted that when implantation is performed prior to the formation of strained layer, the subsequent growth or deposition of the strained layer on the relaxed layer is preferably performed at a temperature low enough to prevent premature separation or cleaving along plane 17 in the relaxed layer (i.e., prior to the wafer bonding process step). The separation or cleaving temperature is a complex function of the implanted species, implanted dose, and implanted material. However, typically, premature separation or cleaving may be avoided by maintaining a deposition or growth temperature below about 500° C.

Handle Wafer Structure

Referring now to FIG. 1B, the handle wafer structure 11 comprises a handle wafer or substrate 16 having a dielectric layer 15 on a surface thereof to provide an insulating layer in the final SSOI structure. The dielectric layer may be any electrically insulating material suitable for use in an SSOI structure, such as a material comprising SiO₂, Si₃N₄, aluminum oxide, or magnesium oxide. In one preferred embodiment, the dielectric layer is SiO₂. However, it is to be noted that in some instances, it may alternatively be preferable to use a material for the dielectric layer which has a melting point which is higher than the melting point of pure SiO₂ (i.e., higher than about 1700° C.). Examples of such materials are silicon nitride (Si₃N₄), aluminum oxide, and magnesium oxide. Without being held to a particular theory, it is generally believed that using a dielectric layer with a higher melting point helps prevent possible relaxation of the transferred strained layer that may occur during subsequent processing, possibly due to softening of the underlying dielectric layer at temperatures typically used during device fabrication (approximately 1000-1200° C.).

The dielectric layer may be applied according to any known technique in the art, such as thermal oxidation, wet oxidation, or thermal nitridation. Generally speaking, the dielectric layer is grown to a substantially uniform thickness sufficient to provide the desired insulating properties in the final SSOI structure. Typically, however, the dielectric layer has a thickness of at least about 1 nm, preferably at least about 10 nm, and more preferably at least about 50 nm or even about 100 nm. In one preferred embodiment, the dielectric layer has a thickness of about 145 nm.

Wafer Bonding and Transfer of the Strained Layer

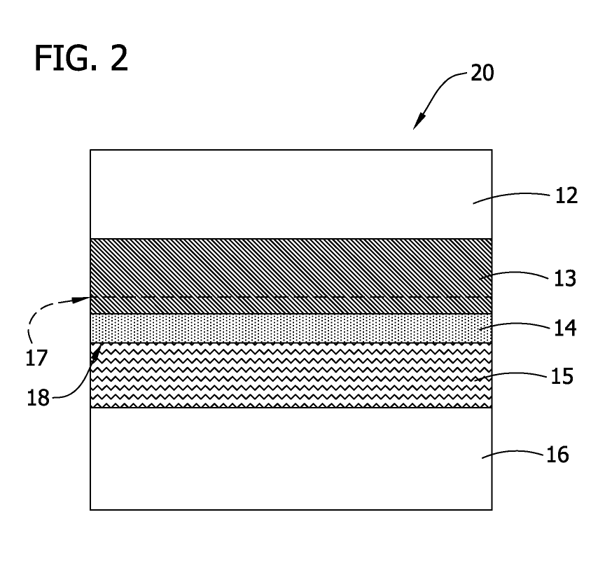

Once the donor wafer structure 10 and handle wafer structure 11 have been prepared, forming the final SSOI structure involves transferring the strained silicon layer of the donor wafer structure onto the dielectric layer of the handle wafer structure. Referring now to FIG. 2, generally speaking, this transfer is achieved by contacting the surface of the dielectric layer to the surface of the strained layer in order to form a single, bonded structure 20 (a bond interface 18 being formed between the two surfaces), and then cleaving or separating the bonded structure along the separation or cleave plane 17 in the relaxed layer.

Prior to bonding, the surfaces of the strained silicon layer and/or the dielectric layer may optionally undergo cleaning and/or a brief etching, planarization, or plasma activation to prepare their surfaces for bonding using techniques known in the art. Without being held to a particular theory, it is generally believed that the quality of the surface of the strained silicon layer in the final SSOI structure is, in part, a function of the quality of the surface prior to bonding. Additionally, the quality of both surfaces prior to bonding will have a direct impact on the quality or strength of the resulting bond interface.

In some instances, therefore, the strained layer and/or the dielectric layer may be subjected to one or more of the follow procedures in order to obtain, for example, a low surface roughness (e.g., a roughness of less than about 0.5 nm root mean square (RMS)) prior to bonding: (i) planarization by, for example, CMP and/or (ii) cleaning by, for example, a wet chemical cleaning procedure, such as a hydrophilic surface preparation process (e.g., an RCA SC1 clean process wherein the surfaces are contacted with a solution containing ammonium hydroxide, hydrogen peroxide, and water at a ratio of, for example, 1:2:50 at about 65° C. for about 20 minutes, followed by a deionized water rinse and drying). One or both of the surfaces may also optionally be subjected to a plasma activation after, or instead of, the wet cleaning process to increase the resulting bond strength. The plasma environment may include, for example, oxygen, ammonia, argon, nitrogen, diborane, or phosphine.

The donor wafer structure is bonded to the handle wafer by bringing the surfaces of the strained layer 14 and the dielectric layer 15 together to form a bond interface 18, as shown in FIG. 2. Generally speaking, wafer bonding may be achieved using essentially any technique known in the art, provided the energy employed to achieve formation of the bond interface is sufficient to ensure that the integrity of the bond interface is sustained during subsequent processing (i.e., layer transfer by separation along the cleave or separation plane 17 in the relaxed layer). Typically, however, wafer bonding is achieved by contacting the surface of the strained layer and the dielectric layer at a reduced pressure (e.g., about 50 mTorr) and at room temperature, followed by heating at an elevated temperature (e.g., at least about 200° C., 300° C., 400° C., or even 500° C.) for a sufficient period of time (e.g., at least about 10 seconds, 100 seconds, 1000 seconds, or even 10,000 seconds). For example, the heating may take place at about 300° C. for about 3600 seconds. The resulting interface may have a bond strength that is greater than about 500 mJ/m², about 1000 mJ/m², about 1500 mJ/m², or about 2000 mJ/m².

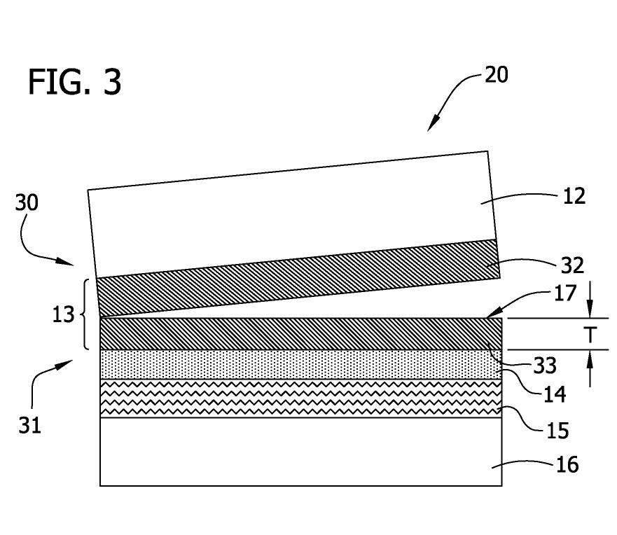

Referring now to FIG. 3, after the bond interface 18 has been formed, the resulting bonded structure 20 is subjected to conditions sufficient to induce a fracture along the separation or cleave plane 18 within the relaxed layer 13. Generally speaking, this fracture may be achieved using techniques known in the art, such as thermally or mechanically induced cleaving techniques. Typically, however, fracturing is achieved by annealing the bonded structure at a temperature of at least about 200° C., 300° C., 400° C., 500° C., 600° C., 700° C. or even 800° C. (the temperature being in the range of, for example, about 200° C. to about 800° C., or from about 250° C. to about 650° C.) for a period of at least about 10 seconds, 100 seconds, 1000 seconds, or even 10,000 seconds (with higher temperatures requiring shorter anneal times, and vice versa), under an inert (e.g., argon or nitrogen) atmosphere or ambient conditions.

In this regard it is to be noted that in an alternative embodiment, this separation may be induced or achieved by means of mechanical force, either alone or in addition to annealing.

Referring again to FIG. 3, upon separation, two structures (30 and 31) are formed. Since the separation of the bonded structure 20 occurs along the separation of cleave plane 17 in the relaxed layer 13, a portion of the relaxed layer remains part of both structures (i.e., a portion of the relaxed layer is transferred along with the strained layer). Structure 30 comprises the donor wafer 12 and some portion 32 of the relaxed layer 13. Structure 31 comprises the handle wafer 16, the dielectric layer 15, and the strained silicon layer 14, on the surface of which is a residual portion 33 of the relaxed layer 13.

The thickness (T) of the residual relaxed layer 33 is approximately equivalent to the depth to which ions were implanted into the relaxed layer prior to wafer bonding. Accordingly, T is typically greater than about 10 nm, 15 nm or even 20 nm. For example, in some instances the residual layer may optionally be at least about 30 nm, 50 nm, 80 nm, 100 nm, 120 nm thick or more.

After separation has been achieved, the resulting structure 31 (i.e., the structure with the strained layer thereon, after separation), may be further annealed at an elevated temperature (e.g., a temperature in the range of about 600-1250° C.) to further strengthen the bond between the strained layer and the dielectric layer.

Finishing the Strained Silicon Surface after Layer Transfer

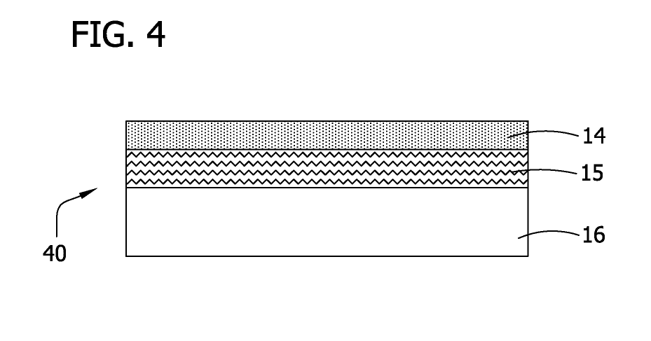

Referring now to FIGS. 3 and 4, after the strained silicon layer 14 has been transferred to the handle wafer 16 to form structure 31, structure 31 is subjected to additional processing to produce a strained silicon surface having desirable features for device fabrication thereon. Such features are defined further herein below and include, for example, reduced surface roughness, and/or a reduced concentration of light point defects, and/or being substantially free of Ge on the surface of the strained layer. Specifically, substantially all of the residual relaxed silicon-comprising layer 33 is removed via a wet etching process using an etchant comprising NH₄OH, H₂O₂, and H₂O. This etchant is available commercially in various formulations and is commonly referred to as an “SC1” etchant. As shown in FIG. 4, the final SSOI structure 40 comprises a silicon handle wafer 16 and a strained silicon layer 14 with a dielectric layer 15 therebetween, the surface of the strained layer being substantially free of the relaxed layer 33.

The appropriate etching composition is selected according to various factors, including the precise composition of the residual relaxed layer (e.g., SiGe layer) and the selectivity of the etchant, wherein “selectivity” refers to the preferential rate at which the etchant removes the relaxed layer material in relation to the strained layer material in accordance with the present invention. In one preferred embodiment, the selectivity of the etchant is evaluated with respect to the rate at which the relaxed SiGe layer is removed compared to the rate at which the strained silicon layer is removed. This ratio of SiGe:Si removal is at least, in part, dependent upon the concentration of Ge in the relaxed SiGe layer, as well as the etchant composition. Generally speaking, higher selectivity is preferred so that the residual relaxed SiGe layer is removed quickly while retaining as much of the strained silicon layer as possible. I.e., the etching process preferably takes place quickly while removing the residual relaxed layer, but abruptly stops once substantially all of the relaxed layer is removed.

As previously noted, the concentration of Ge in the residual layer is at least about 10% Ge, and in some instances may be at least about 15%, about 20%, about 25%, about 35%, about 50% or more (e.g., 60%, 70%, 80%, 90% or more). In one preferred embodiment, however, the SiGe layer has a Ge concentration in the range of at least about 10% to less than about 50%, or from at least about 15% to less than about 35%, with a concentration of about 20% Ge being most preferred.

Typically, the etchant comprises NH₄OH, H₂O₂, and H₂O in a ratio sufficient to remove the residual relaxed SiGe layer from the handle wafer with a selectivity of SiGe:Si of at least about 3:1. Preferably, however, the etchant comprises NH₄OH, H₂O₂, and H₂O in a ratio sufficient to achieve a selectivity of at least about 3.5:1, more preferably at least about 4:1, still more preferably at least about 4.5:1, and still more preferably at least about 5:1 or more.

Generally, the etchant may comprise NH₄OH:H₂O₂:H₂O in a ratio from about 1:1:200 to about 1:1:10, or from about 1:1:100 to about 1:1:25. Alternatively, the etchant comprises NH₄OH:H₂O₂:H₂O in a ratio from about 1:2:200 to about 1:2:10, or from about 1:2:100 to about 1:2:25. In one preferred embodiment, the etchant comprises NH₄OH:H₂O₂:H₂O in a ratio of about 1:2:50.

Generally speaking, the duration of the etching process and the temperature at which the process takes place are sufficient to substantially remove the residual relaxed SiGe layer, as detailed elsewhere herein. Typically, however, the handle wafer is exposed to the etchant for between about 10 min and about 500 min, preferably between about 10 min and about 400 min and more preferably between about 10 min and about 300 min. Additionally, the handle wafer is typically etched at a temperature of between about 10° C. to about 100° C., preferably between about 20° C. and about 90° C., and even more preferably between about 30° C. and about 80° C. (with longer etching times being used for lower temperatures, and vice versa). In one embodiment, the etching takes place at about 65° C. for about 200 min.

During the etching process, agitation is typically applied to facilitate the removal of the residual relaxed SiGe layer, thus typically enabling shorter durations for etching to be achieved. In one preferred embodiment, megasonic agitation or treatment is employed. Megasonic etching is carried out in accordance with this invention at a power level typically ranging from about 5 to about 1500 watts. In other embodiments, however, the power of the megasonic etching may range from about 10 to about 1250 watts, from about 25 to about 1000 watts, from about 50 to about 750 watts, or from about 200 to about 600 watts.

The etching process of this invention produces an SSOI structure having a surface with desirable features for subsequent device fabrication. One such feature is the degree to which the residual relaxed layer has been “substantially removed,” i.e., the extent to which the SSOI surface is “substantially free” of the residual relaxed layer. This feature can be measured by determining the level of non-silicon elements remaining on the SSOI surface after the etching process. Here, the detection is focused on the non-silicon elements that were originally comprised in the relaxed layer. For example, in the embodiment of the invention wherein SiGe is the relaxed layer, the level of residual Ge on the SSOI surface remaining from the relaxed SiGe layer is measured. Residual Ge may interfere with subsequent device fabrication or operation. Therefore, in accord with this invention, after etching, the strained silicon surface is substantially free of the relaxed layer, and thus comprises less than about 1.0×10¹⁰ Ge atoms/cm², and preferably comprises less than about 7.5×10⁹ Ge atoms/cm², less than about 5.0×10⁹ Ge atoms/cm², less than about 7.5×10⁸ Ge atoms/cm², or even less than about 5.0×10⁸ Ge atoms/cm². Most preferably, the SSOI surface comprises essentially no detectable Ge atoms (the currently detection limit being about 3.0×10⁸ Ge atom/cm²).

In this regard it is to be noted that the concentration of residual Ge in the strained layer may be determined using means known in the art, such as for example by Inductively-Coupled Plasma-Mass Spectroscopy (ICP-MS) (e.g. HP4500 ICP-MS by Agilent Technology).

In another aspect of this invention, the resulting etched surface of the strained silicon layer also has a reduced concentration of light point defects, or LPDs. Light point defects are one of a number of defects that limit the yield of viable devices that may be obtained from a given wafer or, in the present instance, a strained silicon on insulator structure. Such defects are detectable using techniques known in the art, including for example SurfScan SP1 by KLA-Tencor.

While an overarching goal is to totally eliminate the LPDs on the SSOI surface, LPDs may still form during processing. As such, the size and concentration of such LPDs is preferably reduced as much as possible. Stated otherwise, while some silicon technology produces either a high concentration of LPDs having minimal size as preferable or a low concentration of relatively large size LPDs, the immediate invention produces SSOI surfaces with a low concentration of relatively smaller sized LPDs. Specifically, according to this invention, the SSOI surface comprises less than about 0.35 LPDs/cm², said LPDs having an average latex sphere equivalent diameter of less than about 1 micron, preferably less than about 0.5 microns, and even more preferably less than about 0.3 microns. Preferably, the SSOI surface comprises less than about 0.30 LPDs/cm², less than about 0.25 LPDs/cm², less than about 0.2 LPDs/cm², less than about 0.15 LPDs/cm², or less than about 0.10 LPDs/cm². Most preferably, the SSOI surface comprises essentially no detectable LPDs (LPDs must be at least 0.3 microns in diameter to be detectable under current detection limits).

In yet another aspect of this invention, the strained silicon surface has a low surface roughness, which leads to more reliable device fabrication thereon. Generally, the RMS roughness of the strained silicon surface is less than about 1.0 nm. Preferably, the RMS roughness of the strained silicon surface is less than about 0.75 nm, more preferably less than about 0.5 nm, and still more preferably less than about 0.25 nm.

Strained silicon-on-insulator structures manufactured according to this invention may be used in the manufacture of any devices wherein reduced leakage currents, lower capacitance, and enhanced carrier mobility are desirable characteristics. For example, the SSOI structure of this invention is suitable for use in the manufacture of EMOS, PMOS, MOSFETs, FinFETs, CMOS, and bipolar-CMOS devices. This list is in no way intended to be restrictive or comprehensive.

The present invention is further illustrated by the following Example.

### EXAMPLE

A crude SOI structure was prepared using common techniques in the art, such that, after separation, the resulting structure comprised the handle wafer, the SiO₂ layer, the strained silicon layer thereon, and a residual relaxed SiGe layer on the strained silicon layer, the residual relaxed layer having a thickness of 120 nm. This structure was then exposed to NH₄OH:H₂O₂:H₂O etchant having a ratio of 1:2:50 for 240 min at about 65° C., while a megasonic treatment of about 1500 W was applied, in order to substantially remove the residual relaxed layer from the surface of the strained layer.

The resulting strained silicon surface was evaluated for RMS roughness, residual Ge concentration, and LPD concentration. The silicon surface showed an RMS roughness of about 0.8 nm using a 30 μm×30 μm field of view. Further, the residual Ge concentration was measured to be about 1.0×10¹⁰ Ge atoms/cm². Finally, the LPD concentration was detected to be about 0.35 LPDs/cm², while the diameter was measured to be about 0.15 μm or larger of Latex sphere equivalent.

The present invention is not limited to the above embodiments and can be variously modified. The above description of preferred embodiments is intended only to acquaint others skilled in the art with the invention, its principles and its practical application so that others skilled in the art may adapt and apply the invention in its numerous forms, as may be best suited to the requirements of a particular use.

With reference to the use of the word(s) “comprise” or “comprises” or “comprising” in this entire specification (including the claims below), it is noted that unless the context requires otherwise, those words are used on the basis and clear understanding that they are to be interpreted inclusively, rather than exclusively, and that it is intended each of those words to be so interpreted in construing this entire specification.

What is claimed is:

1. A method for the preparation of a strained silicon on insulator structure, the method comprising:
forming a relaxed silicon-comprising layer on a surface of a donor wafer;
forming a strained silicon layer on a surface of the relaxed silicon-comprising layer;
forming a dielectric layer on a surface of a handle wafer;
bonding the donor wafer and the handle wafer to form a bonded structure, wherein a bond interface is formed between the strained silicon layer and the dielectric layer;
separating the bonded structure along a separation plane within the relaxed silicon-comprising layer, such that the strained silicon layer on said handle wafer has a residual relaxed silicon-comprising layer on the surface thereof having a thickness of at least about 10 nm; and,
etching the separated handle wafer to substantially remove the residual silicon-comprising layer to expose a surface of the strained silicon layer.

2. The method of claim 1 wherein the relaxed silicon-comprising layer has a lattice constant substantially different than the lattice constant of pure silicon.

3. The method of claim 1, wherein said relaxed silicon-comprising layer comprises SiGe.

4. The method of claim 3 wherein said etching comprises contacting the SiGe layer with an etchant that has a SiGe:Si selectivity ratio of greater than 3:1.

5. The method of claim 1, wherein said etching comprises contacting said residual relaxed silicon-comprising layer with an etchant comprising ammonia.

6. The method of claim 1, wherein said etching is performed using megasonic agitation.

7. The method of claim 1 wherein after said etching, the exposed strained silicon layer surface has a RMS roughness of less than about 1.0 nm.

8. The method of claim 1 wherein after said etching, the exposed strained silicon layer surface has less than about 0.35 LPDs/cm².

9. The method of claim 1 wherein after said etching, the exposed strained silicon layer has a Ge concentration of less than about 1×10¹⁰ Ge atoms/cm².

10. The method of claim 1 wherein ions are implanted into the relaxed silicon-comprising layer substantially along a separation plane at a depth of at least about 10 nm below the surface of the relaxed silicon-comprising layer.

11. The method of claim 1 wherein said handle wafer and said donor wafer have a diameter of at least about 200 mm.

12. The method of claim 1 wherein, after etching, said strained silicon layer has a thickness of between about 1 nm and about 100 nm.

13. A method for the preparation of a strained silicon on insulator structure, the method comprising:
forming a relaxed silicon-comprising layer comprising SiGe having at least about 10% Ge on a surface of a donor wafer;
forming a strained silicon layer on a surface of the relaxed silicon-comprising layer;
forming a dielectric layer on a surface of a handle wafer;
bonding the donor wafer and the handle wafer, wherein a bond interface is formed between the strained silicon layer and the dielectric layer;
separating the bonded structure along a separation plane within the relaxed silicon-comprising layer, such that the strained silicon layer on said handle wafer has a residual relaxed silicon-comprising layer on the surface thereof; and,
etching the separated handle wafer to substantially remove the residual silicon-comprising layer to expose a surface of the strained silicon layer, wherein the etching comprises exposing the handle wafer to an etchant with a selectivity ratio for SiGe:Si of at least about 3:1.

14. The method of claim 13 wherein said etching comprises contacting said residual relaxed silicon-comprising layer with an etchant comprising ammonia.

15. The method of claim 13 wherein after said etching, the exposed strained silicon layer surface has a RMS roughness of less than about 1 nm.

16. The method of claim 13 wherein after said etching, the exposed strained silicon layer surface has less than about 0.35 LPDs/cm².

17. The method of claim 13 wherein after said etching, the exposed strained silicon layer has a Ge concentration of less than about 1×10¹⁰ Ge atoms/cm².

18. The method of claim 13 wherein ions are implanted into the relaxed silicon-comprising layer substantially along a separation plane at a depth of at least about 10 nm below the surface of the relaxed silicon-comprising layer.

19. The method of claim 13 wherein said handle wafer and said donor wafer have a diameter of at least about 200 mm.

20. The method of claim 13 wherein, after etching, said strained silicon layer has a thickness of between about 1 nm and about 100 nm.

21. The method of claim 13, wherein said etching is performed using megasonic agitation.

22. A silicon on insulator structure comprising a strained silicon layer, a handle wafer, and a dielectric layer therebetween, wherein a surface of the strained silicon layer has less than about 0.35 LPDs/cm².

23. The silicon on insulator structure of claim 22 the surface of the strained silicon layer has a RMS roughness of less than about 1.0 nm.

24. The silicon on insulator structure of claim 22 wherein said handle wafer has a diameter of at least about 200 mm.

25. The silicon on insulator structure of claim 22 wherein said strained silicon layer has a Ge concentration of less than about 1×10¹⁰ Ge atoms/cm².

26. The silicon on insulator structure of claim 22 wherein the strained silicon layer has a thickness of between about 1 nm and about 100 nm.

27. A silicon on insulator structure comprising a strained silicon layer, a handle wafer, and a dielectric layer therebetween, wherein the surface of the strained silicon layer has less than about 1×10¹⁰ Ge atoms/cm² and an RMS roughness of less than about 1 nm.

28. The silicon on insulator structure of claim 27 wherein the strained silicon layer surface has less than about 0.35 LPDs/cm².

29. The silicon on insulator structure of claim 27 wherein said handle wafer has a diameter of at least about 200 mm.

30. The silicon on insulator structure of claim 27 wherein said strained silicon layer has a Ge concentration of less than about 7.5×10⁹ Ge atoms/cm².

31. The silicon on insulator structure of claim 27 wherein the strained silicon layer has a thickness of between about 1 nm and about 100 nm.
